(19) United States
(12) Patent Application Publication
(10) Pub. No.: US 2010/0164064 A1
(43) Pub. Date: Jul. 1, 2010

(54) Capacitor and Method for Manufacturing the Same

(76) Inventor: Hyun Dong KIM, Yuseong-gu (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/643,821

(22) Filed: Dec. 21, 2009

(30) Foreign Application Priority Data
Dec. 31, 2008 (KR) 10-2008-0138083

(51) Int. Cl. H01L 29/92; H01L 21/02

(52) U.S. Cl. 257/532; 438/393; 257/E29.343; 257/E21.011

(57) ABSTRACT

A capacitor and methods for manufacturing the capacitor are disclosed. The method may include forming a first electrode on a substrate, forming a dielectric layer on the first electrode, the dielectric layer having a first silicon oxide (SiO₂) layer, a zirconium-doped hafnium oxide (Zr-doped HfO₂) layer and a second silicon oxide layer sequentially, and forming a second electrode on the dielectric layer.

### CROSS REFERENCE TO RELATED APPLICATION

This application claims the benefit of Korean Patent Application No. 10-2008-0138083, filed on Dec. 31, 2008, which is hereby incorporated by reference as if fully set forth herein.

### BACKGROUND OF THE DISCLOSURE

1. Field of the Disclosure

The present invention relates to a semiconductor device, more particularly, to a capacitor and a method for manufacturing the capacitor.

2. Discussion of the Related Art

As usage of semiconductor devices has increased, demands for fast and large-sized capacitors have also been increasing. For such a fast capacitor, the resistance of the capacitor electrodes is typically reduced to reduce the frequency dependence of the capacitor. For a large-sized capacitor, the thickness of a dielectric substance between the capacitor electrodes is reduced, a material having a high permittivity is used as dielectric layer, or an area of the capacitor electrodes is increased.

A capacitor used in a semiconductor device may be categorized based on its structure, such as MOS type, P—N type, Polycrystalline silicon-Insulator-Polycrystalline silicon (PIP) type, Metal-Insulator (Oxide)-Metal (MIM) type, etc.

Non-MIM type capacitors may use single-crystal silicon or polycrystalline silicon as a material for at least one electrode. However, such single-crystal or polycrystalline silicon has limitations in reducing the resistance of the capacitor electrodes because of the material characteristics. As a result, MIM type capacitors having metal capacitor electrodes with lower resistance are commonly used in applications requiring fast capacitors.

Such capacitors having a MIM type structure use metal layers as electrodes and a high-k material as a dielectric layer.

### SUMMARY OF THE DISCLOSURE

Accordingly, the present disclosure is directed to a capacitor and a method for manufacturing a capacitor.

Embodiments of the present invention enable reduction of the thickness of the capacitor, and provide a capacitor including a dielectric layer having a high permittivity.

Additional advantages, objects, and features of the disclosure will be set forth at least in part in the description which follows, and will become apparent to those skilled in the art upon examination of the following disclosure or may be learned from practice of the invention. The objectives and other advantages of the invention may be realized and attained by the structures particularly pointed out in the written description and embodied by the claims appended hereto, as well as the appended drawings.

To achieve these objects and other advantages and in accordance with the purpose of the invention, as embodied and broadly described herein, in a first aspect, the present invention relates to a method for manufacturing a capacitor that includes forming a first electrode a substrate; forming a dielectric layer on the first electrode the dielectric layer comprising a first silicon oxide (SiO₂) layer, a zirconium-doped hafnium oxide (Zr-doped HfO₂) layer and a second silicon oxide layer; and forming a second electrode on the dielectric layer.

In another aspect, the present invention relates to a capacitor including a first electrode on a substrate; a dielectric layer comprising a first silicon oxide (SiO₂) layer, a zirconium-doped hafnium oxide (Zr-doped HfO₂) layer and a second silicon oxide (SiO₂) layer on the first electrode; and a second electrode on the dielectric layer.

It is to be understood that both the foregoing general description and the following detailed description of the present invention are exemplary and explanatory, and are intended to provide further explanation of the invention as claimed.

A capacitor according to the present invention comprises a dielectric layer that uses silicon oxide layers and a zirconium-doped hafnium oxide (Zr-doped HfO₂) layer. As a result, a low VCC voltage may be useable, and leakage currents may be reduced such that a thin film device having a high density capacitance may be provided.

### BRIEF DESCRIPTION OF THE DRAWINGS

The accompanying drawings, which are included to provide a further understanding of the present disclosure and which are incorporated in and constitute a part of this application, illustrate embodiment(s) of the disclosure and together with the description serve to explain the principle(s) and embodiment(s) of the disclosure. In the drawings:

FIG. 1 is a cross-sectional diagram illustrating an exemplary capacitor according to an exemplary embodiment of the present invention; and

FIGS. 2 to 4 are cross-sectional views illustrating structures formed in an exemplary method for manufacturing a capacitor according to exemplary embodiments of the present invention.

### DESCRIPTION OF SPECIFIC EMBODIMENTS

Reference will now be made in detail to various embodiments of the present invention, examples of which are illustrated in the accompanying drawings. Wherever possible, the same reference numbers will be used throughout the drawings to refer to the same or like parts.

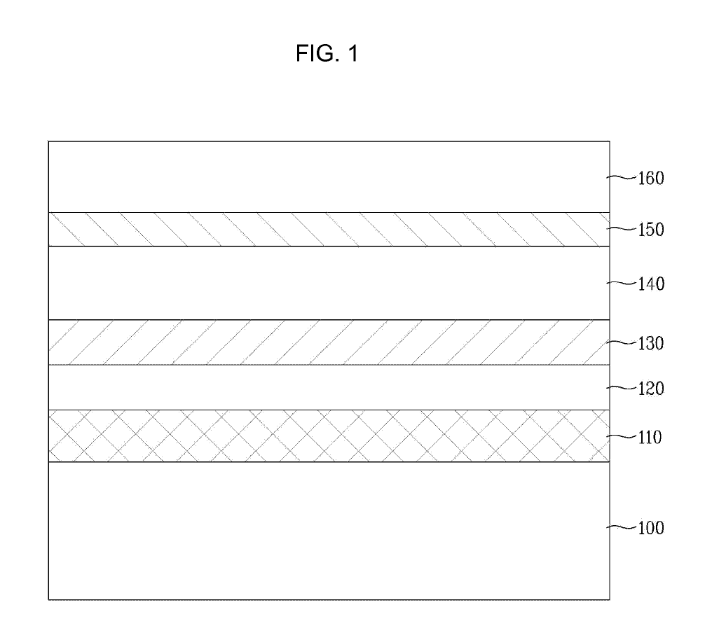

A capacitor according to exemplary embodiments will be now described with reference to FIG. 1.

As shown in FIG. 1, a capacitor according to exemplary embodiments of the present invention may include an insulation layer 110 formed on a substrate 100, a first electrode 120, first silicon oxide layer 130, a Zr-doped HfO₂ layer 140, second silicon oxide layer 150 and second electrode 160.

The first and second silicon oxide layers (SiO₂) 130 and 150 are generally deposited to a thickness of about 1 nm˜2 nm with a Zr-doped HfO₂ layer 140 disposed therebetween. The silicon oxide layers 130 and 150 and the Zr-doped HfO₂ layer are used as a dielectric layer. As a result, a low VCC voltage may be employed, and leakage currents may be reduced. In addition, the present capacitor provides a thin film device having a high density capacitance.

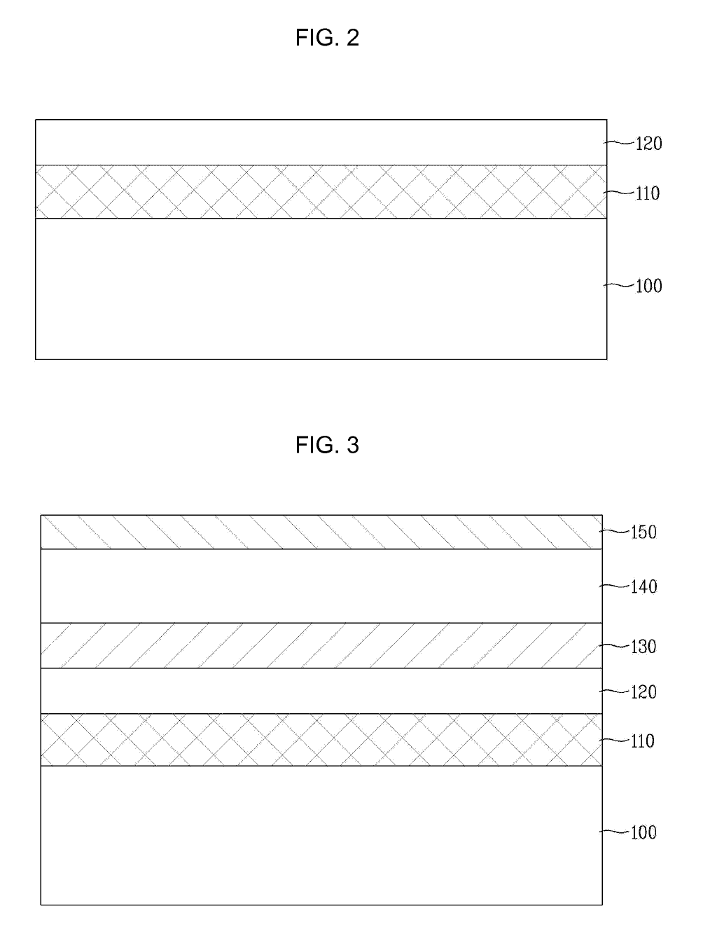

A method for manufacturing a capacitor according to exemplary embodiments of the present invention will be now described with reference to FIGS. 2 to 4.

FIGS. 2 to 4 are cross-sectional views to explain an exemplary embodiment of a method for manufacturing a capacitor.

As shown in FIG. 2, a first (e.g., lower) insulation layer 110 is formed on the substrate 100, and a first electrode 120 is formed on insulation layer 110. In some embodiments, insulation layer 110 may be formed by, e.g., deposition of a dielectric material (e.g., SiO₂), then photolithographic patterning and etching, followed by removal of the photoresist pattern by plasma etching (e.g., using an oxygen-based plasma) or chemical stripping. In embodiments where substrate 100 is silicon, a hard mask pattern (e.g., silicon nitride on silicon oxide) may be defined, leaving an area for forming insulating layer 110 exposed, and the exposed area of substrate 100 may be oxidized at elevated temperatures (e.g., 800-1000° C.) in an oxygen atmosphere to form insulating layer 110, followed by removal of the hard mask pattern by wet etching (e.g., using aqueous phosphoric acid and dilute [buffered] HF).

In case of a metal-oxide-metal (MIM) type capacitor, lower electrode 120 may comprise a metal layer and/or a conductive metal compound layer, for example, a titanium, aluminum, and/or titanium nitride (TiN) layer. In the case of a polycrystalline silicon-insulator-polycrystalline silicon (PIP) type capacitor, first electrode 120 may comprise a polycrystalline silicon layer. For example, first electrode 120 may be formed by deposition of a layer of material, then photolithographic patterning and etching, followed by removal of the photoresist pattern by, e.g., plasma etching (e.g., using an oxygen-based plasma) or chemical stripping.

Other devices (for example, transistors) may also be formed on or in the substrate 100. In this case, an impurity region such as a source/drain region may be formed in the substrate 100, and the source/drain region may be connected to the lower electrode 120 via a contact and/or interconnect passing over and/or through the insulation layer 110.

Although the capacitor shown in the drawings may have a plate shape, the first electrode 120 may have various other shapes, for example, a comb-like structure having a main backbone and a plurality of fingers or teeth interleaved with the fingers or teeth of the complementary electrode, a serpentine structure, or a cylinder a dynamic random access memory (DRAM). In the comb-like structure and serpentine structure, the first and second electrodes may be in the same plane and may be formed from the same materials.

As shown in FIG. 3, the first SiO₂ layer 130 is deposited to a thickness of about 1 nm˜2 nm. In certain embodiments (e.g., when first electrode 120 comprises a metal layer), first SiO₂ layer 130 may be formed by chemical vapor deposition of SiO₂, then (if necessary and/or desired) defined by photolithographic patterning and etching. In other embodiments (e.g., when electrode 120 comprises polysilicon), first SiO₂ layer 130 may be formed by oxidation of the surface of electrode 120 at an elevated temperature (e.g., about 800-1200° C.) in an oxygen atmosphere.

In some embodiments, to form Zr-doped HfO₂ layer 140, Zirconium (Zr) may be doped in a HfO₂ layer to about 4˜7% (or any value therein; by atoms) with respect to Hafnium (Hf) atoms by, e.g., reactive magnetron co-sputtering of Zr on successively deposited layers of HfO₂. The Zr-doped HfO₂ layer 140 may be formed to a thickness of about 10 nm˜20 nm (or any value therein). The HfO₂ may be formed by Atomic Layer Deposition (ALD) or Metal Organic Chemical Vapor Deposition (MOCVD). In the case of using ALD, one or more source gases and oxidant(s) may be alternately injected into a chamber containing substrate 100. In case of using MOCVD, the source gas(es) and oxidant(s) may be injected together into a chamber containing substrate 100.

Notably, by using nitrous oxide (N₂O) as an oxidant for oxidation of Hf during a deposition process, the thickness of an interface oxide layer (e.g., SiO₂ layer 130) formed between the lower electrode 120 and the HfO₂ layer 140 may be reduced, and surface characteristics of the HfO₂ layer may be improved.

More specifically, TEMAH (Hf[N(C₂H₅) (CH₃)]₄), TDEAH (Hf[N(C₂H₅)₂]₄) and/or TDMAH (Hf[N(CH₃)₂]₄) may be used as an Hf source gas to form an HfO₂ layer, no matter which deposition method is used.

For example, in the case of ALD, an Hf source gas may be supplied by using a bubbler maintained at a temperature of about 20˜150° C. (or any value therein) and employing a carrier gas including N₂ or Ar gas. After deposition of a layer of HfO₂, a purge gas may then be supplied to a chamber containing substrate 100 to purge the inside of the chamber. Such deposition/purge processes, including one or more Zr doping steps via sputtering as previously described herein, may be repeated until a HfO₂ layer having a predetermined or targeted thickness and a predetermined or targeted Zr doping concentration is formed. Typically, an inert gas (e.g., Ar, N₂, etc.) is used as purge gas.

For example, in case of using MOCVD, an Hf source gas may be supplied to the inside of the chamber via a first gas supply line. An oxidant gas such as nitrous oxide (N₂O), nitrosyl oxide (NO), oxygen (O₂), ozone (O₃), etc. may be supplied separately or simultaneously to the inside of the chamber via a second gas supply line.

The chamber is maintained at a temperature of approximately between 250˜450° C. (or any value therein) and a pressure approximately between 0.1˜2 Torr (or any value therein). The supply amount of the carrier gas may be approximately 50˜500 sccm (or any value therein), and the supply amount of oxidant may be approximately 500˜3000 sccm (or any value therein).

Accordingly, the deposition process of HfO₂ may be performed in a single-type, batch-type or semi-batch-type chamber. In certain embodiments, Zr may be deposited to effect doping of an HfO₂ layer, e.g., by depositing Zr as described above between sequential ALD or MOCVD deposition steps for forming HfO₂ layers. For example, HfO₂ may be deposited via ALD or MOCVD, then Zr may be deposited by sputtering, then an additional layer of HfO₂ may be deposited, etc. The amount of Zr deposited on intervening layers of HfO₂ may be chosen to afford a targeted doping level (e.g., 4-7%) of Zr relative to Hf in Zr-doped HfO₂ layer 140.

In an alternative embodiment, the Zr-doped HfO₂ layer 140 may be formed by employing a Zr source gas (e.g., TEMAZ (Zr[N(C₂H₅)(CH₃)]₄), TDEAZ (Zr[N(C₂H₅)₂]₄), TDMAZ (Zr[N(CH₃)₂]₄), or any other suitable organozirconium compound) in an ALD or MOCVD process in combination with an Hf source gas to deposit Zr-doped HfO₂ layer 140.

The second silicon oxide layer (SiO₂) 150 may be deposited on the Zr-doped HfO₂ 140 to a thickness of 1 nm˜2 nm in an oxygen atmosphere by, e.g., ALD or CVD and, if necessary or desired, photolithographic masking and patterning.

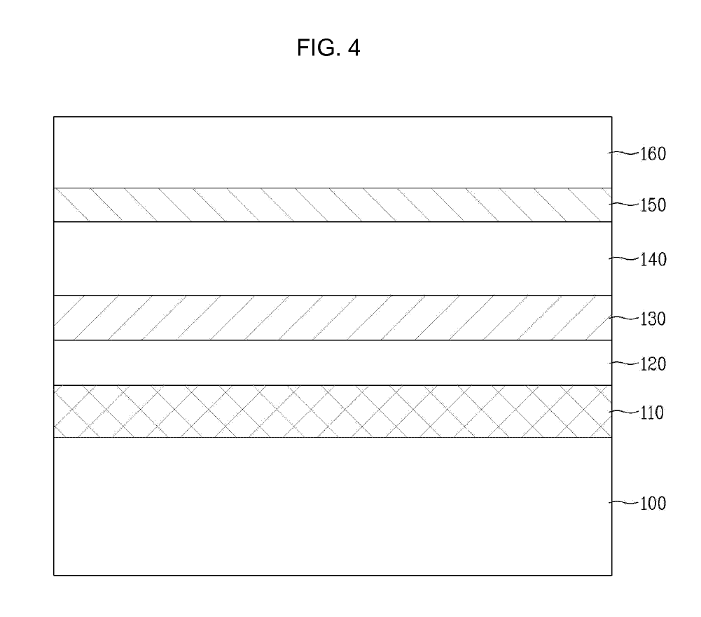

As shown in FIG. 4, the second electrode 160 is formed on the second silicon oxide layer 150. As an alternative to photolithographic patterning of individual layers in the present capacitor, when the first electrode, the capacitor dielectrics and the second electrode are stacked, a photoresist pattern can be formed on the uppermost (e.g., the second electrode) layer of the capacitor, and all of the layers can be patterned/etched sequentially using the photoresist pattern as a mask. Alternatively, a second mask can be used to pattern the lowest layer (e.g., the first electrode) when it is not electrically connected to an underlying structure through an underlying contact or via.

Through the above processes, a capacitor having a first electrode 120, dielectric layers 130, 140 and 150, and a second electrode 160 layered sequentially thereon can be formed using the above processes. After that, the capacitor may be annealed at a temperature of about 400-450° C. (e.g., 420° C., or any other value therein).

The second electrode 160 and the first electrode 120 may both be formed from a single layer of TiN, or each electrode may comprise one or more Ti, Al, TiN and/or polycrystalline silicon layers. For example, in some embodiments, second electrode 160 may be formed by depositing a first layer (e.g., Ti or TiN), then depositing a second layer thereon different from the first layer (e.g., TiN or Al, respectively), providing a second electrode 160 comprising two or more different layers of material. In the case of Al, the second electrode 160 may further comprise a third layer (e.g., ok Ti and/or TiN). The first electrode 120 may have a similar structure. Second electrode 160 and/or each layer therein may be formed by deposition and photolithographic patterning as previously described herein.

It will be apparent to those skilled in the art that various modifications and variations can be made without departing from the spirit or scope of the invention. Thus, it is intended that the present invention covers modifications and variations of this invention provided they come within the scope of the appended claims and their equivalents.

What is claimed is:

1. A method for manufacturing a capacitor, comprising:
forming a first electrode on a substrate;
forming a dielectric layer on the first electrode, the dielectric layer having a first silicon oxide (SiO₂) layer, a zirconium-doped hafnium oxide (Zr-doped HfO₂) layer and an second silicon oxide layer; and
forming a second electrode on the dielectric layer.

2. The method of claim 1, wherein the first silicon oxide layer has a thickness of about 1 nm˜2 nm.

3. The method of claim 1, wherein the second silicon oxide layer has a thickness of about 1 nm˜2 nm.

4. The method of claim 1, wherein the zirconium-doped hafnium oxide layer has a zirconium (Zr) content of 4˜7% with respect to hafnium (Hf).

5. The method of claim 1, wherein forming the Zr-doped hafnium oxide layer comprises introducing TEMAH (Hf[N(C₂H₅)(CH₃)]₄), TDMAH (Hf[N(C₂H₅)₂]₄) or TDMAH (Hf[N(CH₃)₂]₄) as a Hf source gas into a chamber.

6. The method of claim 5, wherein a carrier gas including nitrogen (N₂) and/or argon (Ar) is introduced simultaneously with the Hf source gas.

7. The method of claim 5, wherein forming the Zr-doped hafnium oxide layer further comprises introducing an oxidant gas into the chamber.

8. The method of claim 7, wherein the oxidant gas comprises nitrous oxide.

9. The method of claim 7, wherein forming the Zr-doped hafnium oxide layer further comprises introducing zirconium into the chamber.

10. The method of claim 9, wherein forming the Zr-doped hafnium oxide layer comprises alternating (i) introducing the Hf source gas and the oxidant gas and (ii) introducing zirconium into the chamber.

11. The method of claim 1, wherein the first and/or second electrodes comprise one or more titanium nitride (TiN) layers and/or one or more polysilicon layers.

12. A capacitor, comprising:
a first electrode on a substrate;
a dielectric layer comprising a first silicon oxide (SiO₂) layer, a zirconium-doped hafnium oxide (Zr-doped HfO₂) layer and a second silicon oxide (SiO₂) layer on the first electrode; and
a second electrode on the dielectric layer.

13. The capacitor of claim 12, wherein the first and second silicon oxide (SiO₂) layers have a thickness of about 1 nm˜2 nm.

14. The capacitor of claim 12, wherein the Zr-doped HfO₂ layer has a thickness of about 10 nm˜20 nm.

15. The capacitor of claim 12, wherein the zirconium-doped hafnium oxide layer has a zirconium (Zr) concentration of about 4˜7% with respect to hafnium (Hf).

16. The capacitor of claim 12, further comprising an insulating layer on the substrate.

17. The capacitor of claim 12, wherein the first and/or second electrodes comprise titanium nitride.

18. The capacitor of claim 12, wherein the first and/or second electrodes comprise one or more TiN layers and/or one or more polysilicon layers.

19. A method for manufacturing a capacitor, comprising:
forming first and second electrodes on a substrate;
forming a dielectric layer on and/or between the first and second electrodes, the dielectric layer having a first silicon oxide layer, a zirconium-doped hafnium oxide layer on the first silicon oxide layer and a second silicon oxide layer on the zirconium-doped hafnium oxide layer.
